(19) United States
(12) Patent Application Publication
(10) Pub. No.: US 2014/0374901 A1
(43) Pub. Date: Dec. 25, 2014

(54) SEMICONDUCTOR PACKAGE AND METHOD OF FABRICATING THE SAME

(71) Applicant: Samsung Electronics Co., Ltd, Suwon-si (KR)

(72) Inventor: Ma Huishu, Suzhou (CN)

(73) Assignee: Samsung Electronics Co., Ltd, Suwon-si (KR)

(21) Appl. No.: 14/307,807

(22) Filed: Jun. 18, 2014

(30) Foreign Application Priority Data
Jun. 21, 2013 (CN) 201310249959.4
Oct. 30, 2013 (KR) 10-2013-0130443

(51) Int. Cl. H01L 23/00

(52) U.S. Cl. CPC H01L 24/29; H01L 24/14; H01L 2224/1411; H01L 2224/29005
USPC 257/737; 257/778

(57) ABSTRACT

A semiconductor package including: a substrate including a grounding pattern and a pad, the grounding pattern and the pad being separated and electrically insulated from each other; a semiconductor chip mounted on the substrate, the semiconductor chip including an active surface and an inactive surface opposite to the active surface; a bump interposed between the active surface and the pad to electrically connect the active surface to the pad; and a conductive member including at least a portion, the at least a portion being disposed on the inactive surface and electrically connected to the grounding pattern.

### CROSS-REFERENCE TO RELATED APPLICATIONS

This application claims priority under 35 U.S.C. §119 from Korean Patent Application No. 10-2013-0130443, filed on Oct. 30, 2013 in the Korean Intellectual Property Office, and Chinese Patent Application No. 201310249959.4, filed on Jun. 21, 2013 in the State Intellectual Property Office (SIPO) of the People's Republic of China, the disclosures of which are incorporated herein in their entirety by reference.

### BACKGROUND OF THE INVENTION

1. Field of the Invention

The inventive concept relates to a semiconductor package and a method of fabricating the semiconductor package, and more particularly, a semiconductor package having improved electrical performance and a method of fabricating the semiconductor package.

2. Description of the Related Art

A typical semiconductor package includes a semiconductor package having a chip normally mounted on a substrate and a semiconductor package having a flip chip mounted on a substrate. In the semiconductor package having the chip normally mounted on the substrate, the chip has an inactive surface mounted on a chip-supporting portion of the substrate through an adhesive layer and an active surface electrically connected to a pad on a surface of the substrate through a bonding wire, and the pad is electrically connected to an external connecting terminal, such as a solder ball, through a lead positioned inside the substrate. In the semiconductor package having the flip chip mounted on the substrate, the chip has an active surface electrically connected to a pad on a surface of the substrate through a bump, and the pad is electrically connected to an external connecting terminal, such as a solder ball, through a lead positioned inside the substrate.

As the circuitry and layout of a package have become more complicated, the width of a circuit pattern becomes narrower and narrower, and the pitch between circuit patterns becomes smaller and smaller, thereby causing deteriorated signal integrity.

### SUMMARY OF THE INVENTION

The inventive concept provides a semiconductor package having improved electrical performance.

The inventive concept also provides a method of fabricating the semiconductor package.

Additional features and utilities of the present general inventive concept will be set forth in part in the description which follows and, in part, will be obvious from the description, or may be learned by practice of the general inventive concept.

Exemplary embodiments of the present inventive concept provide a semiconductor package including: a substrate including a grounding pattern and a pad, the grounding pattern and the pad being separated and electrically insulated from each other; a semiconductor chip mounted on the substrate, the semiconductor chip including an active surface and an inactive surface opposite to the active surface; a bump interposed between the active surface and the pad to electrically connect the active surface to the pad; and a conductive member including at least a portion, the at least a portion being disposed on the inactive surface and electrically connected to the grounding pattern.

The semiconductor package may further include a connecting member for electrically connecting the at least a portion of the conductive member to the grounding pattern.

The connecting member may include at least one of a conductive paste or a metal wire.

The conductive member may further include at least another portion extending from the at least a portion to be directly and electrically connected to the grounding pattern.

The at least a portion may cover 20 percent or more of an area of the inactive surface.

The at least a portion may cover substantially the entire inactive surface.

The conductive member may include at least one of a conductive adhesive tape or a metal foil.

The substrate may have a first surface on which the grounding pattern and the pad are positioned and a second surface opposite to the first surface, wherein the substrate may further include another pad disposed on the second surface and an inner lead disposed inside the substrate to electrically connect the pad to the another pad, and wherein the semiconductor package may further include an external connecting terminal disposed on the another pad.

The semiconductor package may further include a molded body for encapsulating the pad, the grounding pattern, the semiconductor chip, the bump, and the conductive member.

Exemplary embodiments of the present inventive concept also provide a semiconductor package including: a substrate including a first surface, on which a grounding pattern is disposed, and a second surface opposite to the first surface, a semiconductor chip mounted on the first surface of the substrate, the semiconductor chip not being electrically connected to the grounding pattern; and a ground layer formed on an upper surface of the semiconductor chip.

The ground layer may cover substantially the entire upper surface of the semiconductor chip.

The ground layer may extend along a side of the semiconductor chip and may be connected to the grounding pattern.

The ground layer may include a conductive member including a conductive adhesive tape or a metal foil.

The semiconductor package may further include a connecting member for electrically connecting the ground layer to the grounding pattern.

The connecting member may include a conductive paste or a metal wire.

Exemplary embodiments of the present inventive concept also provide a method of fabricating a semiconductor package, the method including providing an intermediate product including: a substrate including a grounding pattern and a pad, the grounding pattern and pad being separated and electrically insulated from each other; a semiconductor chip mounted on the substrate, the semiconductor chip including an active surface and an inactive surface opposite to the active surface; a bump interposed between the active surface and the pad to electrically connect the active surface to the pad; and a conductive member including at least a portion disposed on the inactive surface.

The method may further include electrically connecting the at least a portion of the conductive member to the grounding pattern.

Exemplary embodiments of the present inventive concept also provide a semiconductor package comprising: a substrate comprising a grounding pattern and a pad, the grounding pattern and the pad being electrically insulated from each other; and a semiconductor chip mounted on the substrate and comprising: an active surface being electrically connected to the pad at selective electrical connection points, and an inactive surface opposite to the active surface and being electrically connected to the grounding pattern.

In an exemplary embodiment, the inactive surface comprises a first conductive portion to cover substantially the entire inactive surface and a second portion to extend from the first portion to the ground pattern.

In an exemplary embodiment, the semiconductor package further comprises: a molding layer which encapsulates the grounding pattern, the pad, the chip and the first and second conductive portions.

In an exemplary embodiment, the first conductive portion and a second portion of the inactive surface include a conductive adhesive material or metal foil.

In an exemplary embodiment, the semiconductor package further comprises a connecting member to be directly and electrically connected at one end thereof to the inactive surface and at another end thereof to the grounding portion.

In an exemplary embodiment, the connecting member comprises at least one of a conductive paste or a metal foil.

In an exemplary embodiment, the semiconductor package further comprises: a molding layer which encapsulates the grounding pattern, the pad, the chip and the connecting member.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a schematic cross-sectional view showing a semiconductor package according to an exemplary embodiment of the inventive concept;

FIG. 2 is a schematic plan view of the semiconductor package shown in FIG. 1 before being molded;

FIG. 3 is a schematic cross-sectional view showing a semiconductor package according to an exemplary embodiment of the inventive concept;

FIG. 4 is a schematic plan view of the semiconductor package shown in FIG. 3 before being molded;

FIGS. 5 through 8 are schematic cross-sectional views sequentially showing a method of fabricating the semiconductor package shown in FIG. 1.

FIG. 9 is a schematic block diagram of a memory card including a semiconductor package, according to an exemplary embodiment of the inventive concept; and

FIG. 10 is a schematic block diagram of an electronic system including a semiconductor package, according to an exemplary embodiment of the inventive concept

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

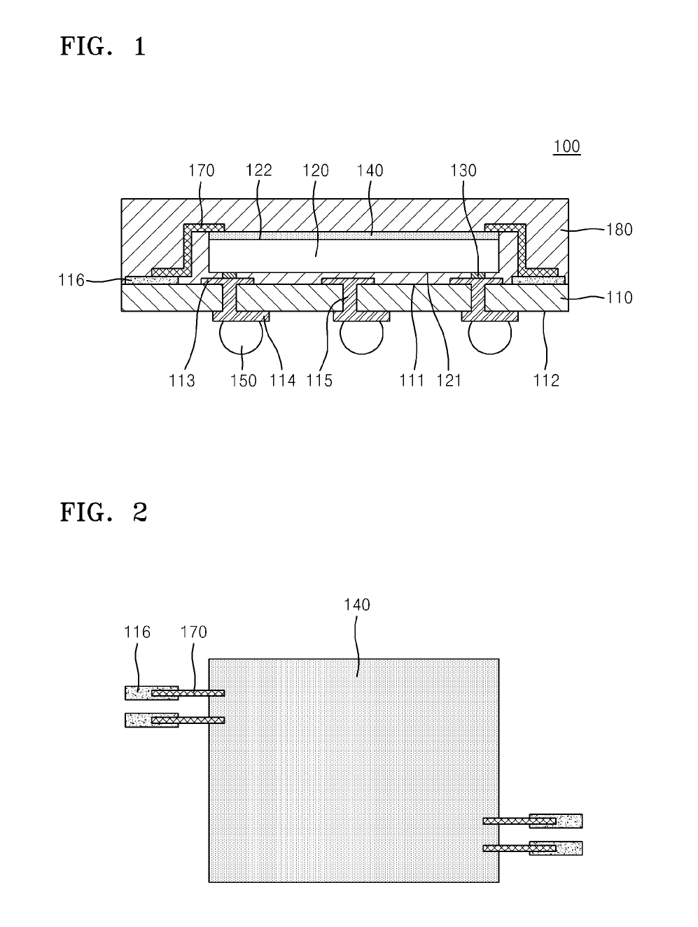

FIG. 1 is a schematic cross-sectional view showing a semiconductor package 100 according to an exemplary embodiment of the inventive concept, and FIG. 2 is a schematic plan view of the semiconductor package 100 shown in FIG. 1 before being molded. Referring to FIGS. 1 and 2, the semiconductor package 100 may include a substrate 110, a semiconductor chip 120 mounted on the substrate 110, and bumps 130 interposed between the substrate 110 and the semiconductor chip 120 to electrically connect the semiconductor chip 120 to the substrate 110. The semiconductor package 100 may include the semiconductor chip 120 invertedly mounted on the substrate 110.

The substrate 110 may be a printed circuit board (PCB). The substrate 110 may have a first surface (for example, an upper surface) 111 and a second surface (for example, a lower surface) 112 opposite to the first surface 111. The substrate 110 may include first pads 113 disposed on the first surface 111, second pads 114 disposed on the second surface 112, and inner leads 115 disposed inside the substrate 110 to electrically connect the first pads 113 to the second pads 114.

The substrate 110 may further include grounding patterns 116 which are disposed on the first surface 111 and are separated and insulated from the first pads 113. In some exemplary embodiments, each of the grounding patterns 116 may have at least a portion not covered by the semiconductor chip 120.

The semiconductor chip 120 may have an active surface 121 and an inactive surface 122 opposite to the active surface 121, and the inactive surface may be, for example, a rear surface of the semiconductor chip 120. The active surface 121 may face the substrate 110, more particularly, the first surface 111 of the substrate 110. The semiconductor chip 120 may include a plurality of pads (not shown) disposed on the active surface 121. The semiconductor chip 120 may include a plurality of sub-semiconductor chips (not shown) sequentially stacked.

The bumps 130 may be disposed between the active surface 121 of the semiconductor chip 120 (for example, the pads on the active surface 121, which are not shown) and the first surface 111 of the substrate 110 (for example, the first pads 113 on the first surface 111) to electrically connect the substrate 110 to the semiconductor chip 120.

In an exemplary embodiment, the semiconductor package 100 may further include external connecting terminals 150 disposed on the second pads 114 to be connected to an external device (not shown) so that the semiconductor chip 120 may be electrically interconnected with the external device through the bumps 130, the first pads 113, the inner leads 115, the second pads 114, and the external connecting terminals 150. In some exemplary embodiments, the external connecting terminals 150 may be solder balls.

In an exemplary embodiment, the semiconductor package 100 may further include a conductive member 140. The conductive member 140 may have at least a portion disposed on the inactive surface 122 of the semiconductor chip 120, and may be electrically connected to at least one of the grounding patterns 116 of the substrate 110. For example, the conductive member 140 may be electrically connected to the grounding patterns 116 of the substrate 110 through a plurality of conductive connecting members 170. In this case, the conductive member 140, the connecting members 170, and the grounding patterns 116 of the substrate 110 may form a grounding path which may direct static electricity generated by the semiconductor chip 120 to ground. Accordingly, the semiconductor package 100 may have improved signal integrity and thus improved electrical performance.

In an exemplary embodiment, the conductive member 140 may cover the entire or substantially the entire inactive surface 122 of the semiconductor chip 120 to form a grounding plane having a large area so that a grounding signal is maximized and the electrical performance of the semiconductor package 100 is significantly improved. However, the inventive concept is not limited thereto. In an exemplary embodiment, the conductive member 140 may cover or occupy 20% or more, preferably 40% or more, more preferably 60% or more, and most preferably 80% or more of the area of the inactive surface 122 of the semiconductor chip 120 to form the grounding plane having a large area so that the grounding signal is maximized and the electrical performance of the semiconductor package is improved. In an exemplary embodiment, the conductive member 140 may further include a portion extending from the inactive surface 122 to cover a side surface of the semiconductor chip 120 substantially perpendicular to the inactive surface 122.

In an exemplary embodiment, the conductive member 140 may include a conductive adhesive tape, a metal foil, or a conductive member in other forms. In an exemplary embodiment, the conductive adhesive tape may be a conductive die attach film (DAF). When the conductive member 140 includes a conductive adhesive tape, the conductive adhesive tape may be attached onto the inactive surface 122 of the semiconductor chip 120. When the conductive member 140 includes a metal foil, a conductive adhesive may be interposed between the metal foil and the inactive surface 122 of the semiconductor chip 120 to adhere the metal foil to the inactive surface 122 of the semiconductor chip 120.

In an exemplary embodiment, the connecting members 170 may include a conductive paste, a metal wire, or a conductive connecting member in other forms. When the connecting members 170 include a conductive paste, the connecting members 170 may be easily applied by injecting, spraying, or dispensing.

Although the conductive member 140 is electrically connected to four grounding patterns 116 of the substrate 110 through four connecting members 170 disposed at approximately corners of the inactive surface 122, respectively, as shown in FIG. 2, the numbers of the connecting members 170 and the grounding patterns 116 are not limited as long as the conductive member 140, the connecting members 170, and the grounding patterns 116 form a proper grounding path.

In an exemplary embodiment, the semiconductor package 100 may further include a molded body 180 for encapsulating the first pads 113 and the grounding patterns 116 on the first surface 111 of the substrate 110 as well as the semiconductor chip 120, the bumps 130, the conductive member 140, and the connecting members 170. The molded body 180 may be made of epoxy molding compound.

According to the exemplary embodiments of the inventive concept, the semiconductor package 100 may have improved signal integrity and thus improved electrical performance.

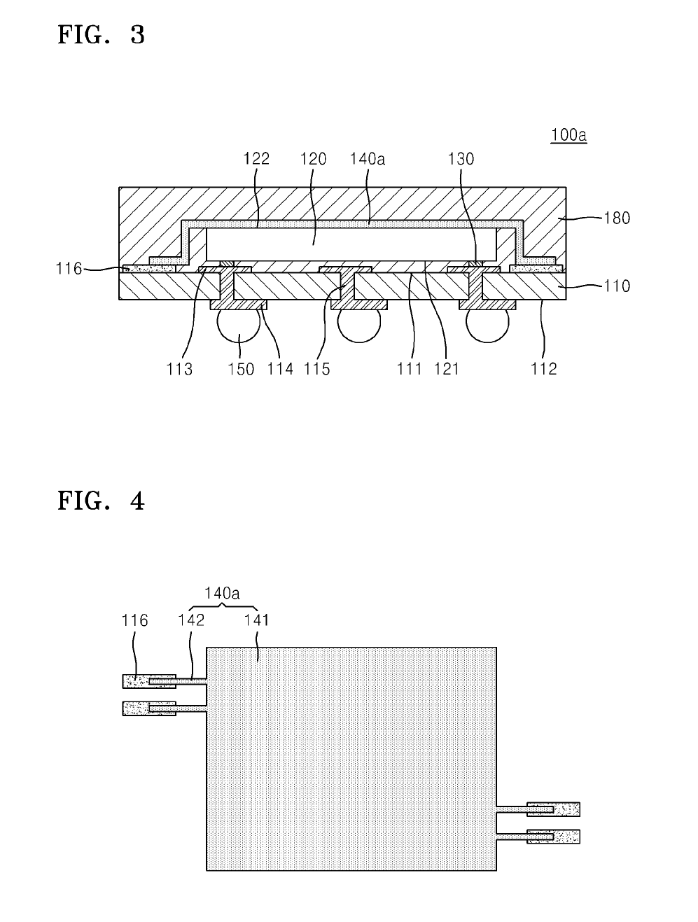

FIG. 3 is a schematic cross-sectional view showing a semiconductor package 100a according to another exemplary embodiment of the inventive concept, and FIG. 4 is a schematic plan view of the semiconductor package 100a shown in FIG. 3 before being molded. The semiconductor package 100a is similar to the semiconductor package 100 described with reference to FIGS. 1 and 2 except for the shape of a conductive member 140a, and thus, a difference between the semiconductor package 100a and the semiconductor package 100 is mainly described below.

Referring to FIGS. 3 and 4, the conductive member 140a may directly extend to the grounding patterns 116 of the substrate 110 from the inactive surface 122 of the semiconductor chip 120 to be electrically connected to the grounding patterns 116 of the substrate 110. Thus, there is no requirement for using a conductive connecting member 170 to connect the conductive member 140a with the grounding patterns 116.

In an exemplary embodiment, the conductive member 140a may include a first portion 141 and a second portion 142 as illustrated in FIG. 4. The first portion 141 may be disposed on the inactive surface 122 of the semiconductor chip 120, and the second portion 142 may extend in a substantially vertical direction from edges of the first portion 141 and then to the grounding pattern 116 of the substrate 110 so that the inactive surface 122 of the semiconductor chip 120 is connected to the grounding pattern 116 of the substrate 110 via only the conductive member 140a.

Although the second portion 142 of the conductive member 140a does not directly cover a side portion of the semiconductor chip 120, which is substantially perpendicular to the inactive surface 122 of the semiconductor chip 120, as shown in FIG. 3, the second portion 142 of the conductive member 140a may extend in a direction perpendicular to the inactive surface 122 while directly covering the side portion of the semiconductor chip 120.

Although the conductive member 140a covers substantially the entire inactive surface 122 of the semiconductor chip 120 as shown in FIGS. 3 and 4, the inventive concept is not limited thereto. In an exemplary embodiment, the first portion 141 of the conductive member 140a may cover or occupy 20% or more, preferably 40% or more, more preferably 60% or more, and most preferably 80% or more of the area of the inactive surface 122 of the semiconductor chip 120 to form a grounding plane having a large area so that a grounding signal is maximized and the electrical performance of the semiconductor package 100a is improved.

Although as shown in FIG. 4, the conductive member 140a has four second portions 142 formed at approximately corners of the inactive surface 122 and is electrically connected to four grounding patterns 116 of the substrate 110 through the four second portions 142, respectively, the numbers of the second portions 142 and the grounding patterns 116 are not limited as long as the conductive member 140a and the grounding patterns 116 form a proper grounding path.

In an exemplary embodiment, the conductive member 140a may include a conductive adhesive tape or a metal foil having a portion suitable for extending to the grounding patterns 116.

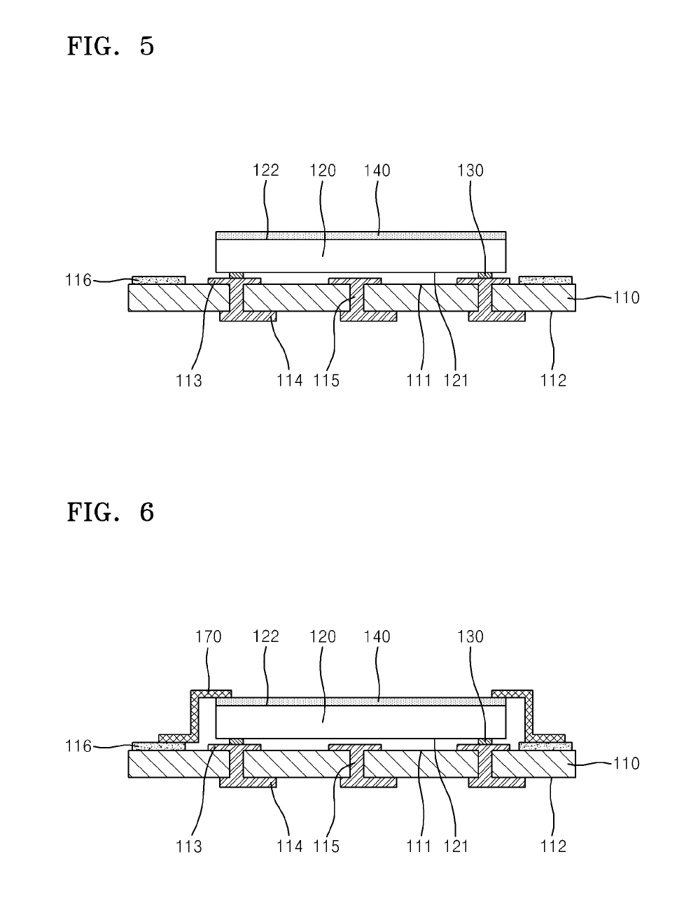

Hereinafter, a method of fabricating the semiconductor package 100 illustrated in FIG. 1 will be described with reference to FIGS. 5 through 8.

FIGS. 5 through 8 are schematic cross-sectional views sequentially showing a method of fabricating the semiconductor package 100 illustrated in FIG. 1.

Referring to FIG. 5, an intermediate product, which includes a substrate 110, a semiconductor chip 120 mounted on the substrate 110, bumps 130 interposed between the substrate 110 and the semiconductor chip 120 to electrically connect the semiconductor chip 120 to the substrate 110, and a conductive member 140 disposed on an inactive surface 122 of the semiconductor chip 120, is provided.

In an exemplary embodiment, the semiconductor chip 120 may be mounted on the substrate 110 using the bumps 130 by a known method, for example, reflowing, and then the conductive member 140 may be disposed on the inactive surface 122 of the semiconductor chip 120. In an exemplary embodiment, the conductive member 140 may be disposed on the inactive surface 122 of the semiconductor chip 120 first, and then the semiconductor chip 120 may be mounted on the substrate 110 using the bumps 130 by a known method, for example, reflowing. The conductive member 140 may include a conductive adhesive tape, a metal foil, or a conductive member in other forms. The conductive adhesive tape may be a conducive die attach film (DAF). When a conductive adhesive tape is used as the conductive member 140, the conductive adhesive tape may be attached onto the inactive surface 122 of the semiconductor chip 120. When a metal foil is used as the conductive member 140, an additional conductive adhesive (not shown) may be interposed between the metal foil and the inactive surface 122 of the semiconductor chip 120 to adhere the metal foil to the inactive surface 122 of the semiconductor chip 120.

The conductive member 140 may cover the entire or substantially the entire inactive surface 122 of the semiconductor chip 120 as shown in FIG. 5, but the inventive concept is not limited thereto. In an exemplary embodiment, the conductive member 140 may cover or occupy 20% or more, preferably 40% or more, more preferably 60% or more, and most preferably 80% or more of the area of the inactive surface 122 of the semiconductor chip 120.

In an exemplary embodiment, the conductive member 140 may further include a portion extending from the inactive surface 122 to cover a side surface of the semiconductor chip 120 substantially perpendicular to the inactive surface 122. In an exemplary embodiment, the conductive member 140 may further include a portion suitable for extending beyond the inactive surface 122 of the semiconductor chip 120 to be connected to grounding patterns 116 of the substrate 110. In this case, the semiconductor package 100a described with reference to FIGS. 3 and 4 may be fabricated.

Referring to FIG. 6, conductive connecting members 170 may be disposed between the conductive member 140 and the grounding patterns 116 of the substrate 110 in order to electrically connect the conductive member 140 to the grounding patterns 116 of the substrate 110. The conductive member 140, the connecting members 170, and the grounding patterns 116 of the substrate 110 may form a grounding path, which improves the signal integrity of the semiconductor package 100 and thus the electrical performance thereof.

The connecting members 170 may be a conductive paste, a metal wire, or a conductive connecting member in other forms. In the case of using a conductive paste as the connecting members 170, the connecting members 170 may be easily applied by injecting, spraying, or dispensing.

Although the conductive member 140 is described here as being electrically connected to the grounding patterns 116 of the substrate 110 through the connecting members 170 as shown in FIG. 6, the inventive concept is not limited thereto. In the case where the conductive member 140 further includes a portion suitable for extending beyond the inactive surface 122 of the semiconductor chip 120 to be connected to the grounding patterns 116 of the substrate 110, the portion may be connected to the grounding patterns 116 of the substrate 110, thus eliminating the requirement for connecting members 170. Particularly, the portion may be directly connected to the grounding patterns 116 of the substrate 110, or the portion may extend on the side surface of the semiconductor chip 120 substantially perpendicular to the inactive surface 122 and then may be connected to the grounding patterns 116 of the substrate 110. Accordingly, a step of arranging the connecting members 170 may be omitted.

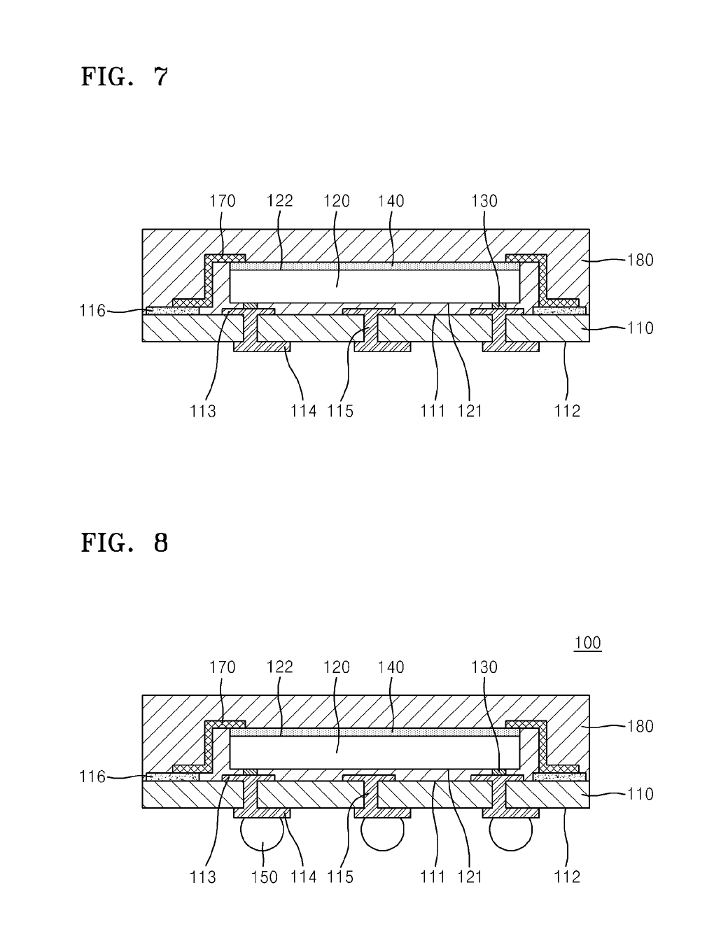

Referring to FIG. 7, a molded body 180 for encapsulating first pads 113 and the grounding patterns 116 on a first surface 111 of the substrate 110 as well as the semiconductor chip 120, the bumps 130, the conductive member 140, and the connecting members 170 may be formed. In an exemplary embodiment, the molded body 180 may be formed of epoxy molding compound by a known method, for example, molding and curing.

Referring to FIG. 8, external connecting terminals 150 for connection with an external device may be disposed on second pads 114 of the substrate 110 so that the semiconductor chip 120 may be electrically interconnected with the external device through the bumps 130, the first pads 113, inner leads 115, the second pads 114, and the external connecting terminals 150. In an exemplary embodiment, solder balls may be arranged as the external connecting terminals 150 by a known method, for example, reflowing. Thus, the fabricating of the semiconductor package 100 is completed.

In an exemplary embodiment, a step of disposing the external connecting terminals 150 described with reference to FIG. 8 may be performed before a step of forming the molded body 180 described with reference to FIG. 7.

The semiconductor package according to any of the above embodiments of the inventive concept may include a conductive member disposed on an inactive surface of a semiconductor chip and electrically connected to grounding patterns to form a grounding path together with the grounding patterns so that the signal integrity of the semiconductor package is improved, thereby improving electrical performance of the semiconductor package. Also, the conductive member may cover or occupy 20% or more of the area of the inactive surface of the semiconductor chip, for example, cover the entire or substantially the entire inactive surface of the semiconductor chip to form a grounding plane having a large area so that a grounding signal is enhanced and the electrical performance of the semiconductor package is improved.

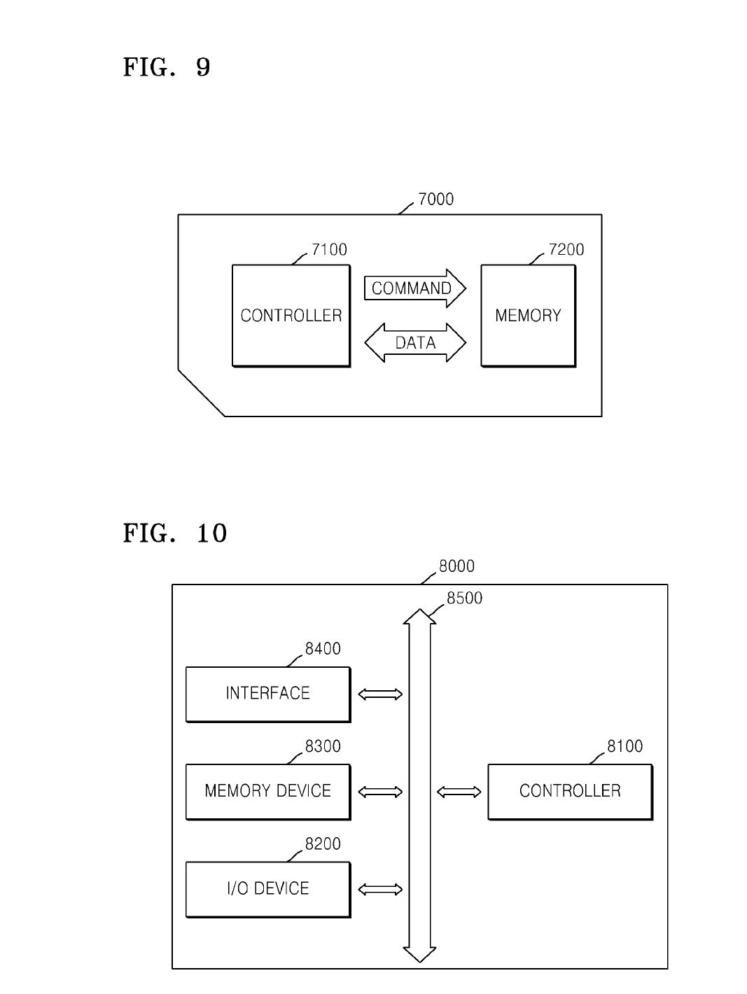

FIG. 9 is a schematic block diagram of a memory card 7000 including a semiconductor package according to an exemplary embodiment of the inventive concept.

Referring to FIG. 9, in the memory card 7000, a controller 7100 and a memory 7200 may be disposed to exchange electrical signals. For example, when the controller 7100 provides an instruction, the memory 7200 may transmit data. The controller 7100 and/or the memory 7200 may include the semiconductor package according to any of the above embodiments of the inventive concept. The memory 7200 may include a memory array (not shown) or a memory array bank (not shown).

The memory card 7000 may include various kinds of memory cards, for example, a memory stick card, a smart media card (SM), a secure digital card (SD), a mini-secure digital card (mini SD), a multimedia card (MMC), etc.

FIG. 10 is a block diagram of an electronic system 8000 including a semiconductor package according to an exemplary embodiment of the inventive concept.

Referring to FIG. 10, the electronic system 8000 may include a controller 8100, an input/output (I/O) device 8200, a memory device 8300, and an interface 8400. The electronic system 8000 may be a mobile system or a system configured to transmit or receive information. The mobile system may be a personal digital assistant (PDA), a portable computer, a web tablet, a wireless phone, a mobile phone, a digital music player, a memory card, or the like.

The controller 8100 may be configured to execute a program and control the electronic system 8000. For example, the controller 8100 may be a microprocessor, a digital signal processor, a microcontroller, or a device similar thereto. The I/O device 8200 may be used to input or output data to or from the electronic system 8000.

The electronic system 8000 may be connected to an external device (e.g., a personal computer (PC) or network) by using the I/O device 8200 to exchange data with the external device. The I/O device 8200 may be, for example, a keypad, a keyboard, or a display device. The memory device 8300 may store codes and/or data required for operations of the controller 8100 and/or store data processed by the controller 8100. The controller 8100 and the memory device 8300 may include the semiconductor package according to any of the above embodiments of the inventive concept. The interface 8400 may be a data transmission path between the electronic system 8000 and other external devices. The controller 8100, the I/O device 8200, the memory device 8300, and the interface 8400 may communicate with one another through a bus 8500.

For example, the electronic system 8000 may be used for a mobile phone, a media player 3 (MP3) player, a navigation device, a portable multimedia player (PMP), a solid-state disk (SSD), or household appliances.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A semiconductor package comprising:
a substrate comprising a grounding pattern and a pad, the grounding pattern and the pad being separated and electrically insulated from each other;
a semiconductor chip mounted on the substrate, the semiconductor chip comprising an active surface and an inactive surface opposite to the active surface;
a bump interposed between the active surface and the pad to electrically connect the active surface to the pad; and
a conductive member comprising at least a portion being disposed on the inactive surface and electrically connected to the grounding pattern.

2. The semiconductor package of claim 1, further comprising:
a connecting member to electrically connect the at least a portion of the conductive member to the grounding pattern.

3. The semiconductor package of claim 2, wherein the connecting member comprises at least one of a conductive paste or a metal wire.

4. The semiconductor package of claim 1, wherein the conductive member further comprises:
at least another portion extending from the at least a portion to be directly and electrically connected to the grounding pattern.

5. The semiconductor package of claim 1, wherein the at least a portion covers 20 percent or more of an area of the inactive surface.

6. The semiconductor package of claim 5, wherein the at least a portion covers substantially the entire inactive surface.

7. The semiconductor package of claim 1, wherein the conductive member comprises at least one of a conductive adhesive tape or a metal foil.

8. The semiconductor package of claim 1, wherein the substrate further comprises:
a first surface on which the grounding pattern and the pad are positioned;
a second surface opposite to the first surface;
another pad disposed on the second surface and an inner lead disposed inside the substrate to electrically connect the pad to the another pad, and
an external connecting terminal disposed on the another pad.

9. The semiconductor package of claim 1, further comprising:
a molded body to encapsulate the pad, the grounding pattern, the semiconductor chip, the bump, and the conductive member.

10. A semiconductor package comprising:
a substrate comprising a first surface on which a grounding pattern is disposed and a second surface opposite to the first surface;
a semiconductor chip mounted on the first surface of the substrate and including a ground layer formed on an upper surface thereof which extends along a side of the semiconductor chip and is connected to the grounding pattern.

11. The semiconductor package of claim 10, wherein the ground layer covers substantially the entire upper surface of the semiconductor chip.

12. The semiconductor package of claim 10, wherein the ground layer comprises a conductive member comprising a conductive adhesive tape or a metal foil.

13. A semiconductor package comprising:
a substrate comprising a grounding pattern and a pad, the grounding pattern and the pad being electrically insulated from each other; and
a semiconductor chip mounted on the substrate and comprising:
an active surface being electrically connected to the pad at selective electrical connection points, and
an inactive surface opposite to the active surface and being electrically connected to the grounding pattern.

14. The semiconductor package of claim 13, wherein the inactive surface comprises a first conductive portion to cover substantially the entire inactive surface and a second portion to extend from the first portion to the ground pattern.

15. The semiconductor package of claim 14, wherein the first conductive portion and a second portion of the inactive surface include a conductive adhesive material or metal foil.

16. The semiconductor package of claim 15, further comprising:
a molding layer which encapsulates the grounding pattern, the pad, the chip and the first and second conductive portions.

17. The semiconductor package of claim 13, further comprising:
a connecting member to be directly and electrically connected at one end thereof to the inactive surface and at another end thereof to the grounding portion.

18. The semiconductor package of claim 17, wherein the connecting member comprises at least one of a conductive paste or a metal foil.

19. The semiconductor package of claim 17, further comprising:
a molding layer which encapsulates the grounding pattern, the pad, the chip and the connecting member.
